(19) United States
(12) Patent Application Publication
(10) Pub. No.: US 2009/0067145 A1
(43) Pub. Date: Mar. 12, 2009

(54) CIRCUIT PATTERN DESIGNING METHOD, WHEREIN AN ELECTROCONDUCTIVE COATING MATERIAL IS USED, AND A PRINTED CIRCUIT BOARD

(75) Inventors: Nobuo Kasagi, Toyama (JP); Yasutaka Kataoka, Toyama (JP)

Correspondence Address: DARBY & DARBY P.C., P.O. BOX 770, Church Street Station, New York, NY, 10008-0770, US

(73) Assignee: SMK Corporation, Tokyo (JP)

(21) Appl. No.: 12/131,474

(22) Filed: Jun. 2, 2008

(30) Foreign Application Priority Data
Jun. 8, 2007 (JP) 2007-152516

(51) Int. Cl. H05K 1/16; H05K 3/12; H05K 7/00

(52) U.S. Cl. 361/782; 427/97.3; 427/79; 361/748

(57) ABSTRACT

In a method of preparing a circuit pattern on a printed circuit board, reflow wiring is performed by printing the circuit pattern on an insulative board with an electroconductive coating material and printing a cream solder in a wiring pattern portion of the circuit pattern to form a metal conductor. Other portions of the printed, electroconductive coating material are arranged to function as any one of a resistor (R), a capacitor (C), and a coil (L), by taking advantage of the resistance and electrostatic capacitance of the electroconductive coating material.

### CROSS-REFERENCE TO RELATED APPLICATION

The present application claims priority under 35 U.S.C. § 119 to Japanese Patent Application No. 2007-152516, filed Jun. 8, 2007, and which is hereby incorporated by reference in its entirety.

The present invention relates to a method of designing a circuit pattern of a printed circuit board, wherein an electroconductive material is used, and to a printed circuit board.

### BACKGROUND OF THE INVENTION

Conventionally, in circuit pattern design, it is assumed that a copper clad board is used, that the circuit needed for wiring is protected with an etching resist, and that the copper foil at other portions is removed by etching.

In contrast, as disclosed by Japanese Unexamined Patent Application Publication No. 2006-28213, a method of forming a circuit pattern directly has been studied in recent years wherein the circuit pattern is screen printed with an electroconductive coating material. Japanese Unexamined Patent Application Publication No. 2006-28213 is incorporated by reference in its entirety herein.

The electroconductive coating material is usually a mixture of metal powder and a thermal setting resin, and its viscosity is adjusted by using an organic solvent.

Because this type of electroconductive coating material has a resin component, its resistivity is on the order of 10⁻⁴, which is approximately 100 times that of the resistivity of copper, i.e., 1.68×10⁻⁶.

Accordingly, if wiring is printed with an electroconductive material, then there is a problem in that the operating current decreases substantially.

### SUMMARY OF THE INVENTION

The present invention solves the abovementioned problems, and an object of the present invention is to provide a method of designing a pattern of a printed circuit that takes advantage of the resistance and electrostatic capacitance of an electroconductive material, in combination with printed circuit board.

A first aspect of the invention provides a method of designing a printed circuit pattern that comprises the step of reflow wiring by printing a circuit pattern on an insulative board with an electroconductive coating material and printing a cream solder in a wiring pattern portion that is needed as a metal conductor.

Here, reflow wiring means forming the wiring that wires electronic parts, which are surface mounted to a printed circuit board, together by printing the wiring with an electroconductive coating material, printing a cream solder on the wiring of this electroconductive coating material, and then reflowing the cream solder by heating.

Thereby, using the solder as metal conductor wiring makes it possible to obtain a printed circuit board that prevents a decrease in the operating current—even if the resistance of the electroconductive coating material is higher than that of the copper foil pattern.

Furthermore, in the circuit portions where soldering is not needed, wettability of the solder with respect to the electroconductive coating material, which serves as a means of lowering the conductor resistance, is not needed; consequently, it is also possible to use an electroconductive coating material with a low conductor resistance in that portion of the wiring.

A second aspect of the invention provides a method of designing a printed circuit board that comprises the step of printing an electroconductive coating material on an insulative board so that it functions as any one of a resistor (R), a capacitor (C), and a coil (L), taking advantage of the resistance and electrostatic capacitance of the electroconductive coating material.

The electroconductive coating material contains a resin component as a binder. Therefore, although its electrical resistance is more than 100 times that of metal, it is possible to take advantage of the stable resistance and electrostatic capacitance exhibited when the electroconductive coating material is printed on an insulative board.

Accordingly, it is possible to obtain a printed circuit board by printing a circuit pattern on an insulative board with an electroconductive coating material, as well as by printing any one of a resistor (R), a capacitor (C), and a coil (L).

The present invention adopts a designing method wherein reflow wiring is performed by printing a wiring pattern portion that is needed as a metal conductor with a cream solder, which makes it possible to design a circuit pattern that overcomes the disadvantage of the high resistance of an electroconductive coating material.

In addition, by designing the pattern width, the pattern shape, and the pattern length taking advantage of the fact that the electroconductive coating material's resistance is high, i.e., approximately 100 times that of a metal conductor like copper, and that the electrostatic capacitance is high, it is possible to use the electroconductive coating material as a resistor, a capacitor, a coil, and the like, and thereby to obtain a low-cost printed circuit board.

### BRIEF DESCRIPTION OF THE DRAWINGS

The invention will become more readily apparent from the Detailed Description of the Invention, which proceeds with reference to the drawings in which:

FIG. 1 provides measurement results relating to the resistance of a pattern that was printed with an electroconductive coating material according to the principles of the present invention;

FIGS. 2(a) and 2(b) illustrate shows an example of a pattern designs according to the present invention; and

FIG. 3 shows an example of a remote control board that was prepared according to the principles of the present invention;

### DETAILED DESCRIPTION OF THE INVENTION

An electroconductive coating material suitable for use in accordance with the present invention is made by Maxell Hokuriku Seiki, Ltd. of Toyama, Japan, and is manufactured by mixing Ag-coated Ni powder and Ag powder, using phenol resin as a binder, and then mixing in oleic acid and an organic solvent, such as butyl carbitol (the coating material recited in the earlier-referenced Japanese Unexamined Patent Application Publication No. 2006-28213). A wiring pattern may be screen printed onto an insulative board with the electroconductive material, after which the board can be dried in a drying oven for approximately 30 min at 160° C.

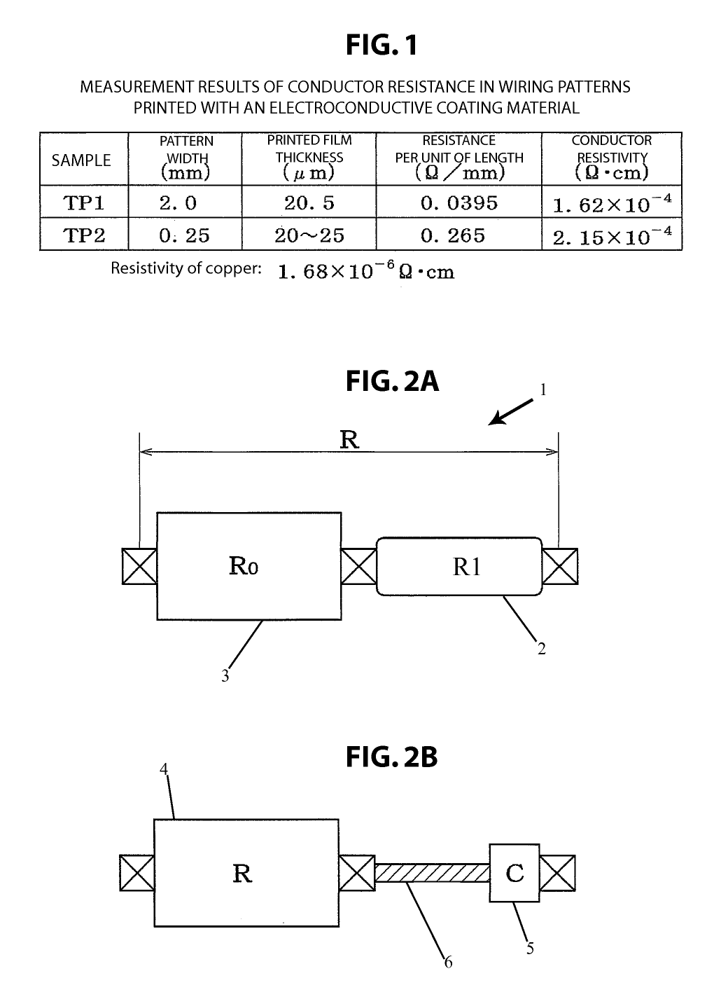

FIG. 1 shows data for two wiring pattern samples: TP1 and TP2 produced in this manner.

In the TP1 sample, the pattern width was set to 2.0 mm, and the wiring pattern was formed by screen printing, which produced a wiring pattern with a film thickness of 20.5 μm.

The measured resistance per millimeter was 0.0395Ω, and therefore the resistivity was 1.62×10⁻⁴ Ω·cm.

When the wiring pattern of the TP2 sample was formed by screen printing with a target pattern width of 0.25 mm, there was some variation in the film thickness in the longitudinal directions, but the resistance was stable at approximately 0.265Ω per millimeter of length.

In this case, the derived resistivity was 2.15×10⁻⁴ Ω·cm.

Accordingly, it was clear that the above value was approximately 100 times the resistivity of copper, which is 1.68×10⁻⁶ Ω·cm.

Based on these measurement results, it was clear that printing a pattern with a width of 1 mm and a length of approximately 11 mm with the electroconductive coating material was equivalent to a resistor of approximately 1Ω.

Based on the above preliminary investigation, if a resistor 1 of resistance R is needed in a circuit as shown in, for example, FIG. 2(a), then it is possible to print a resistor 2 with a width and length that is equivalent to a resistance of R₁ with the electroconductive coating material, and then combine that resistor 2 in series with a resistor 3 having resistance R₀ in the remaining portion. The resistances R₀ and R₁ sum to total R₁.

In addition, in a case wherein a resistor 4 of resistance R and a capacitor 5 of capacitance C are to be connected as shown in FIG. 2 (b), if the wiring pattern is formed with the electroconductive coating material 7, a cream solder 6 is printed thereon and then reflowed, such that the portion defined by solder 6 becomes a metal conductor as a result of the solder 6.

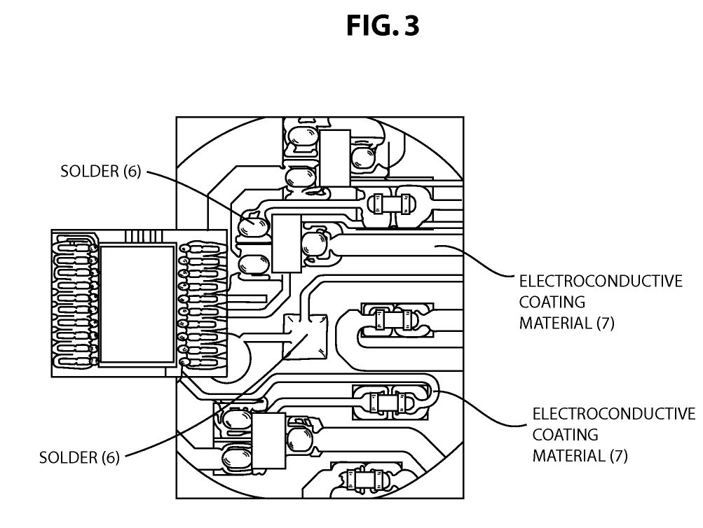

Thus, FIG. 3 shows an example of a remote control board that was actually prepared and evaluated.

When the wiring pattern was formed with just the electroconductive coating material, the circuit leak current was less than 0.04 μA and the oscillation frequency also matched the design target; however, the actual measured operating current was 4.8-5.3 mA, which was lower than the target value of 14 mA; however, the operating current improved when part of the electroconductive coating material wiring was reflow wired using the cream solder.

If the present invention is adapted to a remote control board, then it is also possible to print the carbon contacts as needed.

1. A method of designing a printed circuit board, wherein a circuit pattern of the printed circuit board is designed, comprising the step of:
reflow wiring by printing a circuit pattern on an insulative board with an electroconductive coating material and printing a cream solder in a wiring pattern portion of the circuit pattern to form a metal conductor.

2. A method of designing a printed circuit board, wherein a circuit pattern of the printed circuit board is designed, comprising the step of:
printing an electroconductive coating material on an insulative board so that it functions as any one of a resistor (R), a capacitor (C), or an inductor (L), according to one of a resistance inductance of electrostatic capacitance of the electroconductive coating material, respectively.

3. A printed circuit board having a circuit pattern, wherein
reflow wiring is performed by printing the circuit pattern on an insulative board with an electroconductive coating material and printing a cream solder in a wiring pattern portion of the circuit pattern that is needed as a metal conductor.

4. A printed circuit board having a circuit pattern or an inductor, wherein
the circuit pattern is printed on an insulative board with an electroconductive coating material; and
at least one of a resistor (R), a capacitor (C), or an inductor a coil (L) is printed in the circuit pattern.

5. The printed circuit board of claim 4, wherein the printed circuit pattern includes at least two components selected from the group consisting of resistors (R), inductors (L) and capacitors (C), the at least two components being connected to one or more metal conductors (a) each comprising a portion of the printed circuit pattern and cream solder printed on the portion of the printed circuit pattern.

6. The printed circuit board of claim 4, wherein the at least two components comprise a resistor (R) and a capacitor (C).
